(19) United States
(12) Patent Application Publication
(10) Pub. No.: US 2012/0167975 A1
(43) Pub. Date: Jul. 5, 2012

(54) Solar Cell And Method For Manufacturing The Same

(75) Inventors: Jin-Soo Mun, Yongin-si (KR); Yun Gi Kim, Yongin-si (KR); Ihn Gee Baik, Seongnam-si (KR); Jin Wook Lee, Suwon-si (KR)

(73) Assignee: SAMSUNG ELECTRONICS CO., LTD., Suwon-si (KR)

(21) Appl. No.: 13/166,350

(22) Filed: Jun. 22, 2011

(30) Foreign Application Priority Data
Jan. 3, 2011 (KR) 10-2011-0000242

(51) Int. Cl. H01L 31/0232; H01L 31/18

(52) U.S. Cl. 136/256; 438/71; 257/E31.13

(57) ABSTRACT

A solar cell includes a semiconductor substrate having a texturized surface, the semiconductor substrate including a plurality of recess portions and a plurality of flat portions, an insulation layer on the texturized surface of the semiconductor substrate and an electrode on the plurality of flat portions of the semiconductor substrate. The insulation layer on the plurality of recess portions of the semiconductor substrate is thinner than the insulation layer on the plurality of flat portions of the semiconductor substrate.

### CROSS-REFERENCE TO RELATED APPLICATION

This application claims priority to and the benefit of Korean Patent Application No. 10-2011-0000242, filed in the Korean Intellectual Property Office on Jan. 3, 2011, the entire contents of which are incorporated herein by reference.

### BACKGROUND

1. Field

Example embodiments relate to a solar cell and a method of manufacturing the same.

2. Description of the Related Art

A solar cell is a photoelectric conversion device that transforms solar energy into electrical energy, and has attracted much attention as an infinite but pollution-free next generation energy source.

A solar cell may include p-type and n-type semiconductors and may produce electrical energy by transferring electrons and holes to the n-type and p-type semiconductors, respectively. The solar cell may collect electrons and holes in each electrode when an electron-hole pair (EHP) is produced by solar light energy absorbed in a photoactive layer inside the semiconductors. Further, a solar cell is required to have as much efficiency as possible for producing electrical energy from solar energy.

### SUMMARY

Example embodiments provide a solar cell having improved efficiency by enhancing light absorption and method of manufacturing the same.

According to example embodiments, a solar cell may include a semiconductor substrate having a texturized surface, the semiconductor substrate including a plurality of recess portions and a plurality of flat portions; an insulation layer on the texturized surface of the semiconductor substrate; and an electrode on the plurality of flat portions of the semiconductor substrate, wherein the insulation layer on the plurality of recess portions of the semiconductor substrate is thinner than the insulation layer on the plurality of flat portions of the semiconductor substrate.

The insulation layers on the plurality of recess portions and the plurality of flat portions may have a thickness ratio of about 185:300. The insulation layer may include a first insulation layer on the plurality of flat portions of the semiconductor substrate and a second insulation layer on the entire surface of the semiconductor substrate including the plurality of recess portions and the plurality of flat portions. The first and second insulation layers may include the same material, e.g., a silicon oxide. The insulation layer may further include a third insulation layer including a different material than the first and second insulation layers, e.g., a silicon nitride.

The third insulation layer on the plurality of recess portions of the semiconductor substrate may be thinner than the third insulation layer on the plurality of flat portions of the semiconductor substrate. The plurality of recess portions of the semiconductor substrate may have an inverted pyramid shape, and the insulation layer on the plurality of recess portions may be formed along the sidewall of the plurality of inverted pyramid-shaped recess portions.

The solar cell may further include an emitter layer on the plurality of inverted pyramid-shaped recess portions and under the insulation layer. The semiconductor substrate may be a silicon wafer, and the plurality of recess portions and the plurality of flat portions of the semiconductor substrate may have crystal growth directions (111) and (100) of the silicon wafer, respectively. The semiconductor substrate may have a region doped with a p-type impurity and a region doped with an n-type impurity. The electrode may include a first electrode electrically connected to the region doped with a p-type impurity and a second electrode electrically connected to the region doped with an n-type impurity. The first and second electrodes may be positioned on the same side of the semiconductor substrate or on different sides of the semiconductor substrate.

According to example embodiments, a method of manufacturing a solar cell may include preparing a semiconductor substrate; texturizing a surface of the semiconductor substrate to form a plurality of recess portions and a plurality of flat portions; forming an insulation layer on the surface-texturized semiconductor substrate; and forming an electrode on the plurality of flat portions of the semiconductor substrate. The insulation layer on the plurality of recess portions of the semiconductor substrate may be thinner than the insulation layer on the plurality of flat portions of the semiconductor substrate.

The insulation layer on the plurality of recess portions and the plurality of flat portions of the semiconductor substrate may have a thickness ratio of about 185:300. Texturizing the semiconductor substrate may include forming a first insulation layer on one surface of the semiconductor substrate; patterning the first insulation layer; and etching the semiconductor substrate using the patterned first insulation layer to form the plurality of recess portions.

Forming the insulation layer may include forming a second insulation layer on the entire texturized surface of the semiconductor substrate including the plurality of recess portions and the first insulation layer. The second insulation layer may include the same material as the first insulation layer, e.g., a silicon oxide. The method may further include forming a third insulation layer on the second insulation layer. The third insulation layer may include a different material from the first and second insulation layers, e.g., a silicon nitride. The method may further include forming an emitter layer in the plurality of recess portions of the semiconductor substrate after texturizing the surface of the semiconductor substrate.

### BRIEF DESCRIPTION OF THE DRAWINGS

These and/or other aspects will become apparent and more readily appreciated from the following description of example embodiments, taken in conjunction with the accompanying drawings of which:

FIG. 1 is a top plan view showing a solar cell according to example embodiments,

FIG. 2 is the cross-sectional view of the solar cell cut along a line II-II in FIG. 1,

FIG. 3 is a schematic diagram enlarging one portion of the solar cell of FIG. 2,

FIGS. 4 to 8 are cross-sectional views sequentially showing a method of manufacturing a solar cell according to example embodiments, and

FIG. 9 is a cross-sectional view showing a solar cell according to example embodiments.

### DETAILED DESCRIPTION

Example embodiments will hereinafter be described in detail referring to the following accompanied drawings, and can be easily performed by those who have common knowledge in the related art. However, these embodiments are only examples, and not limited thereto.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, the location of top and bottom portions referring to one side of a semiconductor substrate 110 is illustrated for better understanding and easier description, but the location may be different in a different view. In addition, one side of the semiconductor substrate receiving solar energy is called a front side, and the other opposite side is called a rear side.

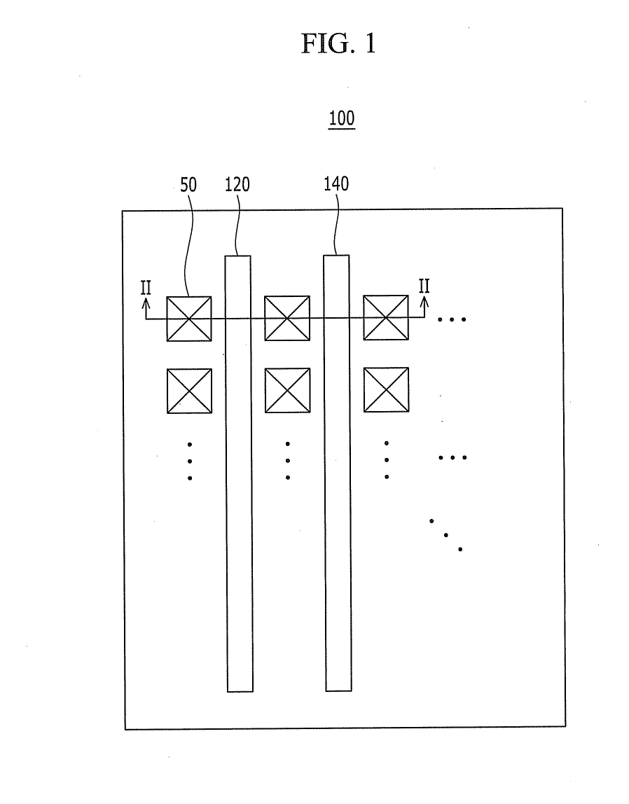

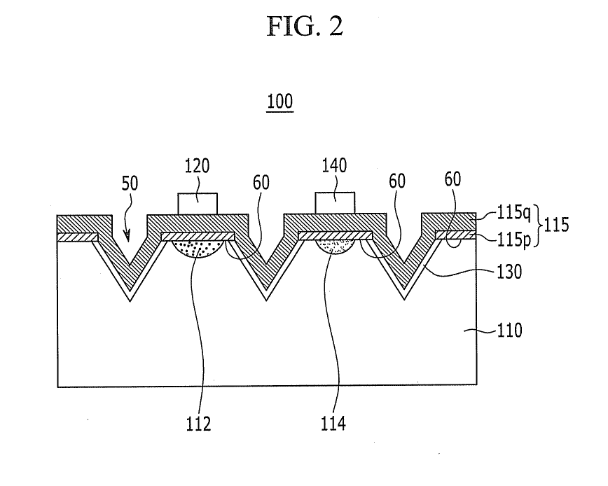

A solar cell 100 according to example embodiments is illustrated, referring to FIGS. 1 and 2. FIG. 1 provides a top plan view showing a solar cell according to example embodiments, and FIG. 2 is a cross-sectional view of the solar cell cut along a line II-II in FIG. 1.

According to example embodiments, a solar cell 100 may include a semiconductor substrate 110, an emitter layer 130, a first doping region 112, a second doping region 114, an insulation layer 115, a first electrode 120, and a second electrode 140.

The semiconductor substrate 110 may be formed of crystalline silicon or a compound semiconductor. The crystalline silicon may include, for example, a silicon wafer. The semiconductor substrate 110 may be doped with a p-type or n-type impurity. Herein, the p-type impurity may be a Group Ill compound, e.g., boron (B), and the n-type impurity may be a Group V compound, e.g., phosphorus (P).

The semiconductor substrate 110 may have a surface-texturized front side. The surface-texturized semiconductor substrate 110 may increase the light absorption rate by enlarging the surface area accepting light and decreasing reflectance, thereby improving efficiency of a solar cell.

The front side of the semiconductor substrate 110 has a plurality of recess portions 50 formed through surface texturization. A plurality of recess portions 50 may be positioned at predetermined or given intervals and may be shaped as inverted pyramids. Neighboring recess portions 50 have a flat surface region 60 therebetween (hereinafter referred to as “flat portion 60”).

Herein, the recess portions 50 and the flat portions 60 respectively have crystal growth directions (111) and (100) of the silicon wafer. The recess portion 50 may be slanted about 52° against the flat portion 60. The semiconductor substrate 110 may include the emitter layer 130 on the recess portions 50.

This emitter layer 130 may be doped with a p-type or n-type impurity, which may be a conductive impurity differing from the semiconductor substrate 110. For example, the semiconductor substrate 110 may be doped with a p-type impurity, and the emitter layer 130 may be doped with an n-type impurity.

The emitter layer 130 may act as a pathway for transferring a charge produced from a photoactive layer of the semiconductor substrate 110 to a following electrode. For example, when an emitter layer 130 is doped with an n-type impurity, the emitter layer 130 may be a pathway through which electrons produced from an active layer move.

The emitter layer 130 may be shaped as an inverted pyramid along the sidewall of the recess portion 50 and may be substantially symmetrical with the inverted pyramid. The flat portion 60 of the semiconductor substrate 110 may include the first and second doping regions 112 and 114 doped with different impurities. Either of the first and second doping regions 112 and 114 may be doped with a p-type impurity in a high concentration. The other of the first and second doping regions 112 and 114 may be doped with an n-type impurity in a high concentration. The insulation layer 115 may be disposed on the semiconductor substrate 110.

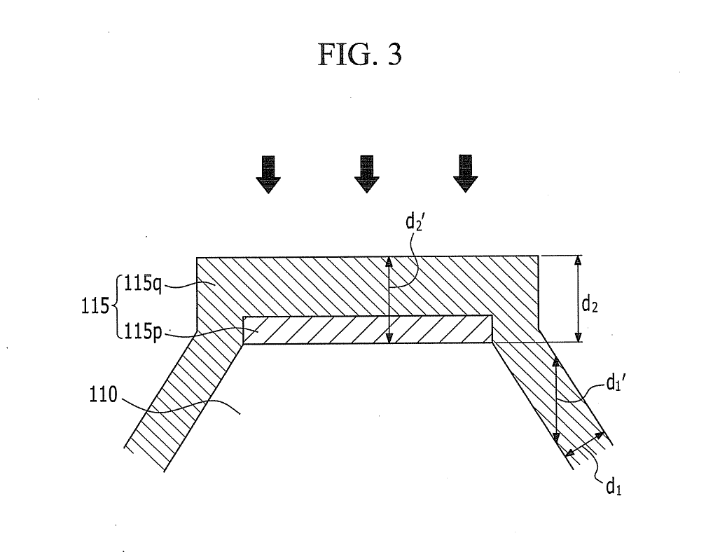

The insulation layer 115 may act as an anti-reflective coating (ARC), for example, decreasing reflectance of light and increasing selectivity of light in a portion of the wavelength region as well as improving the contact characteristic with silicon on the surface of the semiconductor substrate 110, and thus may increase efficiency of a solar cell. Herein, the insulation layer 115 on the recess portion 50 may be thinner than the insulation layer 115 on the flat portion 60. Hereinafter, this will be illustrated in more detail, referring to FIGS. 2 and 3.

FIG. 3 is a schematic diagram enlarging a portion of a solar cell in FIG. 2. Referring to FIGS. 2 and 3, the insulation layer 115 may include first and second insulation layers 115p and 115q. The first insulation layer 115p may be disposed only on the flat portion 60 of the semiconductor substrate 110. The second insulation layer 115q may be disposed on the whole texturized surface of the semiconductor substrate 110 including the flat portion 60 and the recess portion 50.

The second insulation layer 115q on the recess portion 50 has a thickness d1, and the first and second insulation layers on the flat portion 60 have a thickness sum d2. Accordingly, the insulation layer 115 on the recess portion 50 may be thinner than on the flat portion 60.

Herein, the insulation layers 115 on the recess portion 50 and the flat portion 60 may have a thickness ratio d1:d2 of about 185:300. Because the insulation layer 115 is disposed on the recess portion 50 and the flat portion 60 in the thickness ratio d1:d2, light entering the recess portion 50 and the flat portion 60 on one front side of the semiconductor substrate 110 may be controlled to have a substantially equivalent optical path.

Referring to FIG. 3, light vertically enters the flat portion 60 of the semiconductor substrate 110, and passes through the same optical path d2′ as the thickness d2 of the insulation layer 115, thereby reaching the semiconductor substrate 110.

On the contrary, light enters the recess portion 50 at a predetermined or given angle against the semiconductor substrate 110, and passes through a longer optical path d1′ than the actual thickness d1 of the insulation layer 115, thereby reaching the semiconductor substrate 110. When light entering the flat portion 60 and the recess portion 50 of the semiconductor substrate 110 has a different optical path, the insulation layer may not effectively play an anti-reflection coating (ARC) role, thereby deteriorating the photoabsorption rate.

In example embodiments, an insulation layer 115 may be disposed in the thickness ratio d1:d2 on the flat portion 60 and the recess portion 50 of a semiconductor substrate having a texturized surface, and control optical paths d1′ and d2′ are provided to be substantially equivalent regardless of position. Accordingly, the insulation layer may effectively perform an anti-reflection role on the surface of the semiconductor substrate 110 and increase the photoabsorption rate, ultimately improving efficiency of a solar cell.

For example, when the insulation layer 115 on the flat portion 60 is about 300 Å thick, the insulation layer 115 on the recess portion 50 may be about 185 Å thick. In order to satisfy the predetermined or given thickness of an insulation layer 115, the first insulation layer 115p on the flat portion 60 may be about 115 Å thick, while the second insulation layer 115q may be about 185 Å thick on the entire surface of the surface-texturized semiconductor substrate.

Likewise, when the insulation layer 115 on the flat portion 60 is about 1080 Å thick, the insulation layer 115 on the recess portion 50 may be about 666 Å thick. Herein, the first and second insulation layers 115p and 115q may be respectively about 414 Å and 666 Å thick.

First and second electrodes 120 and 140 may be formed on the insulation layer 115. The first and second electrodes 120 and 140 may be positioned on the flat portion 60 of the semiconductor substrate 110, permeated into the insulation layer 115 during firing, and electrically connected to the first and second doping regions 112 and 114, respectively. The first and second electrodes 140 and 120 may have, for example, a relatively fine width ranging from about 1 to 10 μm.

The solar cell generates electricity when the photoactive layer of the semiconductor substrate 110 absorbs solar energy, an electron-hole pair may be produced, and the produced holes may be collected in the first electrode 120, for example, through the first doping region 112, while the electrons are collected in the second electrode 140, for example, through the second doping region 114.

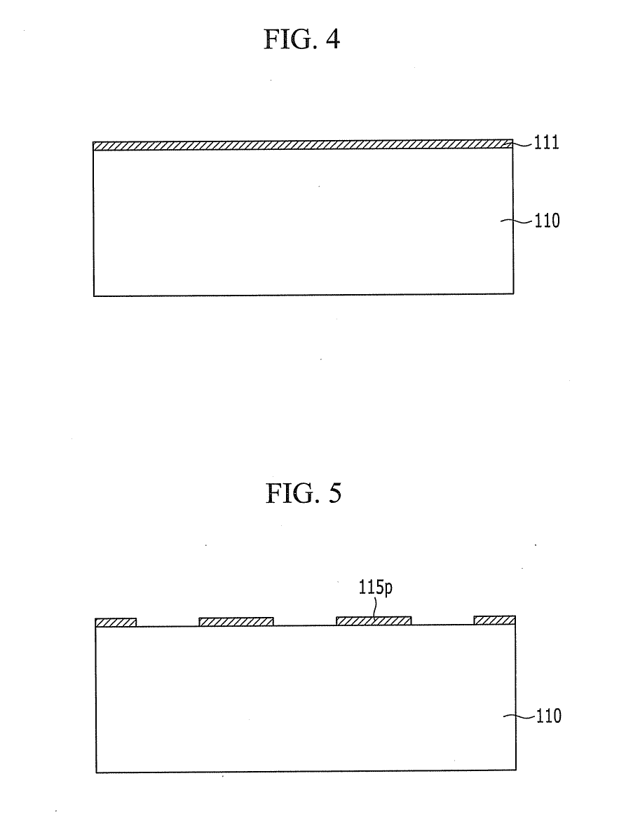

Hereinafter, referring to FIGS. 4 to 8 with FIG. 2, a method of manufacturing a solar cell according to example embodiments is illustrated. FIGS. 4 to 8 are cross-sectional views sequentially showing a method of manufacturing a solar cell according to example embodiments. A semiconductor substrate 110 respectively doped with a p-type or n-type impurity may be prepared.

Referring to FIG. 4, a first insulation layer 111 may be disposed on the semiconductor substrate 110. The first insulation layer 111 may be disposed by forming a silicon oxide in a thermal oxidation method or in a chemical vapor deposition (CVD) method.

Referring to FIG. 5, the first insulation layer 111 may be patterned to expose parts of the semiconductor substrate 110 and form a first patterned insulation layer 115p. Herein, the first patterned insulation layer 115p may have a plurality of openings arranged along a row or column. The openings correspond to a region for the following recess portions 50.

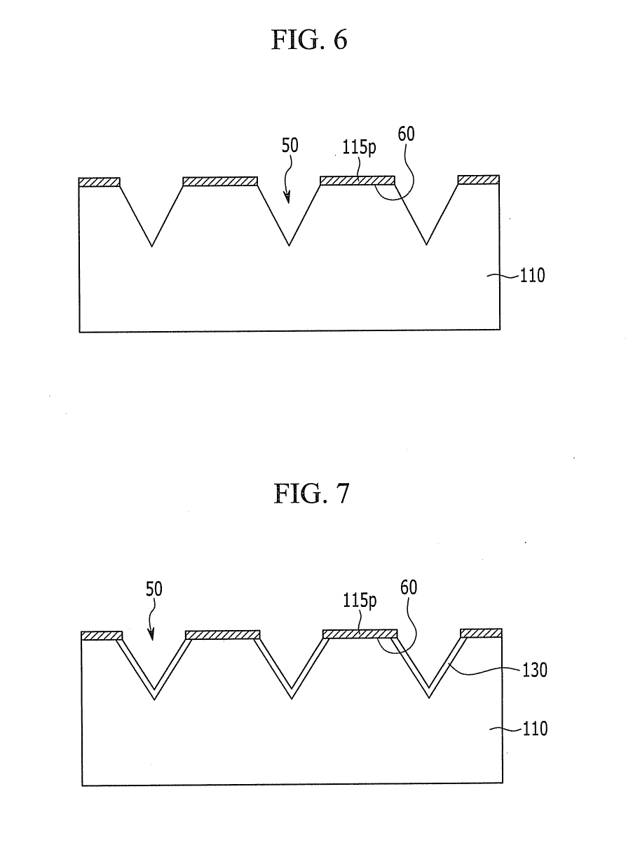

Referring to FIG. 6, the first patterned insulation layer 115p may be used as a mask to texturize the surface of the semiconductor substrate 110. The surface texturization may form a plurality of recess portions 50 with an inverted pyramid shape.

Referring to FIG. 7, an emitter layer 130 may be disposed by using the first patterned insulation layer 115p as a mask and injecting an impurity in the recess portions 50 with an inverted pyramid shape. The emitter layer 130 may be doped with an impurity of a different conductive type from the semiconductor substrate 110. For example, when the semiconductor substrate 110 is doped with a p-type impurity, the emitter layer 130 may be doped with an n-type impurity. This emitter layer 130 may be disposed symmetrically along the sidewall with an inverted pyramid shape.

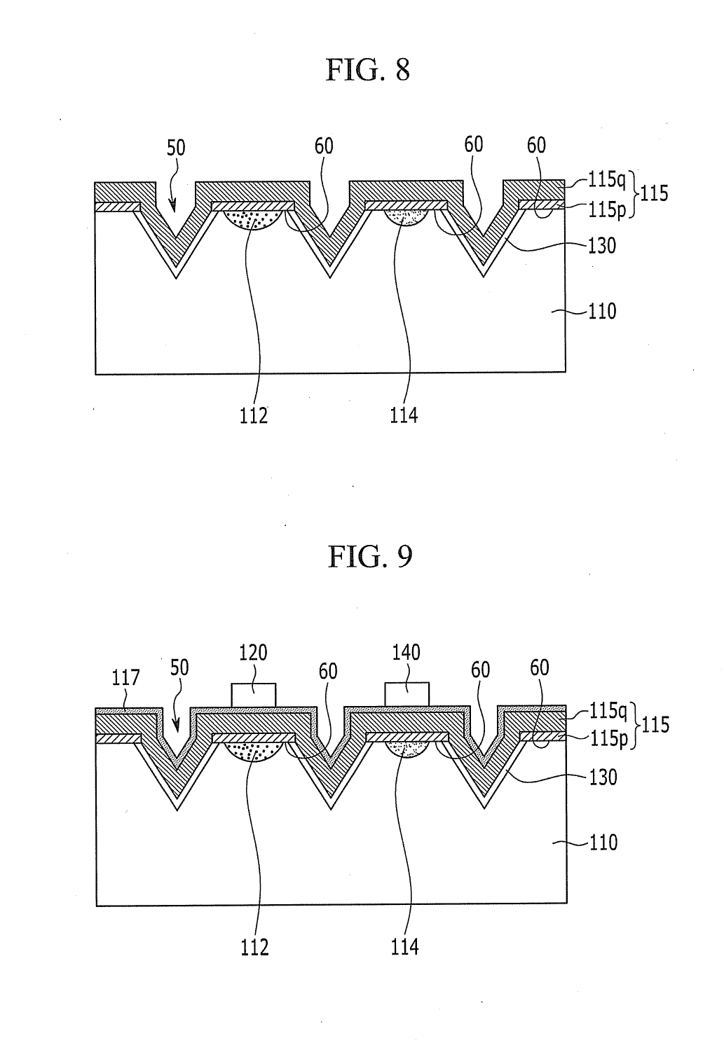

Referring to FIG. 8, the second insulation layer 115q may be disposed on the entirety of one texturized surface of the semiconductor substrate 110. The second insulation layer 115q may be formed of the same material as the first insulation layer 115p, for example, of a silicon oxide.

Because the second insulation layer 115q is disposed on the recess portions 50 of the semiconductor substrate 110 and the first and second insulation layers 115p and 115q are disposed on the flat portions 60 of the semiconductor substrate 110, the insulation layer 115 on the recess portions 50 may be thinner than the insulation layer 115 on the flat portions 60.

If an insulation layer, e.g., a silicon oxide, is directly disposed on the entire surface of a semiconductor substrate 110, silicon crystal growing in directions (100) and (111) may in general have a relative oxidation rate of about 0.707 and about 1.227 due to an interface energy difference. The insulation layer, e.g., silicon oxide, may be formed thicker on the recess portion 50 on which the silicon crystal grows in a direction (111) than on the flat portions 60 on which silicon crystal grows in a direction (100).

Accordingly, to have a thickness sufficient for anti-reflection coating and photoabsorption, the first insulation layer 115p may be disposed to have a predetermined or given thickness on the flat portions 60 of the semiconductor substrate 110, and the second insulation layer 115q may be disposed to have a predetermined or given thickness on the entire surface of the semiconductor substrate 110 to control the thickness on the recess portions 50 and the flat portions 60.

The first and second doping regions 112 and 114 may be formed in the flat portions 60 of the semiconductor substrate 110. The first and second doping regions 112 and 114 may be formed by sequentially injecting different conductive-type impurities. Alternatively, the first and second doping regions 112 and 114 may be formed before forming the insulation layer 115.

Referring to FIG. 2, the first and second electrodes 120 and 140 may be sequentially formed on the flat portions 60 of the semiconductor substrate 110. The first and second electrodes 120 and 140 may be formed, for example, by applying and firing a conductive paste. Herein, the firing may cause the first electrode 120 to be permeated into the insulation layer 115 and become electrically connected to the first doping region 112, and also to cause the second electrode 140 to be permeated into the insulation layer 115 and become electrically connected to the second doping region 114.

Hereinafter, referring to FIG. 9, a solar cell according to example embodiments is illustrated. The same elements will not be further described. FIG. 9 is the cross-sectional view of a solar cell according to example embodiments.

According to example embodiments, a solar cell may include a semiconductor substrate 110 including first and second doping regions 112 and 114, an emitter layer 130, an insulation layer 115 including first and second insulation layers 115p and 115q, and first and second electrodes 120 and 140.

However, the solar cell according to example embodiments may further include a third insulation layer 117 on the insulation layer 115 including first and second insulation layers 115p and 115q. The insulation layer 115 and the third insulation layer 117 may act as an anti-reflection coating (ARC) bi-layer.

Herein, the third insulation layer 117 may be formed of a material differing from that of the insulation layer 115. For example, when the insulation layer 115 is formed of a silicon oxide, the third insulation layer 117 may be formed of a silicon nitride.

The third insulation layer 117, like the insulation layer 115, may be thinner on the recess portions 50 of the semiconductor substrate 110 than on the flat portions 60 of the semiconductor substrate 110. Accordingly, the third insulation layer 117 may have a substantially equivalent optical path for solar light on the recess portions 50 and the flat portions 60, like the insulation layer 115. Herein, the third insulation layer 117 may have a thickness ratio of about 185:300 on the recess portions 50 and the flat portions 60 of the semiconductor substrate 110. For example, the third insulation layer 117 may have a thickness of about 450 Å on the flat portions 60 and a thickness of about 277 Å on the recess portions 50.

Herein, a solar cell with a front contact structure in which first and second electrodes 120 and 140 may be positioned on the front side of a semiconductor substrate is illustrated. However, example embodiments are not limited thereto, but may be applied to a solar cell with a back contact structure in which first and second electrodes 120 and 140 may be positioned on different sides of a semiconductor substrate.

It should be understood that example embodiments described therein should be considered in a descriptive sense only and not for purposes of limitation. Descriptions of features or aspects within each example embodiment should typically be considered as available for other similar features or aspects in other example embodiments.

What is claimed is:

1. A solar cell comprising:
a semiconductor substrate having a texturized surface, the semiconductor substrate including a plurality of recess portions and a plurality of flat portions;
an insulation layer on the texturized surface of the semiconductor substrate; and
an electrode on the plurality of flat portions of the semiconductor substrate,
wherein the insulation layer on the plurality of recess portions of the semiconductor substrate is thinner than the insulation layer on the plurality of flat portions of the semiconductor substrate.

2. The solar cell of claim 1, wherein the insulation layers on the plurality of recess portions and the plurality of flat portions have a thickness ratio of about 185:300.

3. The solar cell of claim 1, wherein the insulation layer includes a first insulation layer on the plurality of flat portions of the semiconductor substrate and a second insulation layer on the entire surface of the semiconductor substrate including the plurality of recess portions and the plurality of flat portions, and
the first and second insulation layers include the same material.

4. The solar cell of claim 3, wherein the first and second insulation layers include a silicon oxide.

5. The solar cell of claim 3, wherein the insulation layer further comprises:
a third insulation layer including a different material than the first and second insulation layers.

6. The solar cell of claim 5, wherein the third insulation layer includes a silicon nitride.

7. The solar cell of claim 5, wherein the third insulation layer on the plurality of recess portions of the semiconductor substrate is thinner than the third insulation layer on the plurality of flat portions of the semiconductor substrate.

8. The solar cell of claim 1, wherein the plurality of recess portions of the semiconductor substrate has an inverted pyramid shape, and
the insulation layer on the plurality of recess portions is formed along the sidewall of the plurality of inverted pyramid-shaped recess portions.

9. The solar cell of claim 8, further comprising:
an emitter layer on the plurality of inverted pyramid-shaped recess portions and under the insulation layer.

10. The solar cell of claim 1, wherein the semiconductor substrate is a silicon wafer, and
the plurality of recess portions and the plurality of flat portions of the semiconductor substrate have crystal growth directions (111) and (100) of the silicon wafer, respectively.

11. The solar cell of claim 1, wherein the semiconductor substrate has a region doped with a p-type impurity and a region doped with an n-type impurity,
the electrode includes a first electrode electrically connected to the region doped with a p-type impurity and a second electrode electrically connected to the region doped with an n-type impurity, and
the first and second electrodes are positioned on the same side of the semiconductor substrate or on different sides of the semiconductor substrate.

12. A method of manufacturing a solar cell, comprising:
preparing a semiconductor substrate;
texturizing a surface of the semiconductor substrate to form a plurality of recess portions and a plurality of flat portions;
forming an insulation layer on the surface-texturized semiconductor substrate; and
forming an electrode on the plurality of flat portions of the semiconductor substrate,
wherein the insulation layer on the plurality of recess portions of the semiconductor substrate is thinner than the insulation layer on the plurality of flat portions of the semiconductor substrate.

13. The method of claim 12, wherein the insulation layer on the plurality of recess portions and the plurality of flat portions of the semiconductor substrate have a thickness ratio of about 185:300.

14. The method of claim 12, wherein texturizing the semiconductor substrate comprises:
forming a first insulation layer on one surface of the semiconductor substrate;
patterning the first insulation layer; and
etching the semiconductor substrate using the patterned first insulation layer to form the plurality of recess portions.

15. The method of claim 14, wherein forming the insulation layer comprises:
forming a second insulation layer on the entire texturized surface of the semiconductor substrate including the plurality of recess portions and the first insulation layer, the second insulation layer including the same material as the first insulation layer.

16. The method of claim 15, wherein the first and second insulation layers include a silicon oxide.

17. The method of claim 15, further comprising:
forming a third insulation layer on the second insulation layer, the third insulation layer including a different material from the first and second insulation layers.

18. The method of claim 17, wherein the third insulation layer includes a silicon nitride.

19. The method of claim 12, further comprising:
forming an emitter layer in the plurality of recess portions of the semiconductor substrate after texturizing the surface of the semiconductor substrate.
